(19) United States
(12) Patent Application Publication
(10) Pub. No.: US 2020/0119699 A1
(43) Pub. Date: Apr. 16, 2020

(54) DISTORTION COMPENSATION DEVICE

(71) Applicant: Mitsubishi Electric Corporation, Chiyoda-ku (JP)

(72) Inventors: Jun NISHIHARA, Chiyoda-ku (JP); Yuichi FUJIMOTO, Shinagawa-ku (JP)

(73) Assignee: Mitsubishi Electric Corporation, Chiyoda-ku (JP)

(21) Appl. No.: 16/337,973

(22) PCT Filed: Apr. 26, 2018
(86) PCT No.: PCT/JP2018/016941

§ 371 Date: Mar. 29, 2019

(30) Foreign Application Priority Data
Jun. 29, 2017 (JP) 2017-127369

(51) Int. Cl. H03F 1/32; H03F 3/24

(52) U.S. Cl. CPC H03F 1/32; H03F 3/45973; H03F 3/24

(57) ABSTRACT

A distortion compensation device includes: a first distributor configured to distribute an input signal into a first route signal and a second route signal; a distortion generation circuit configured to generate a distortion component has non-linear characteristics opposite to those of a device to be compensated in the input first route signal; a second distributor configured to receive the first route signal including the distortion component, distribute the first route signal including the distortion component into a third route signal and a fourth route signal; a first combiner configured to receive the second route signal and the third route signal, and extract and output the distortion component included in the third route signal; a frequency characteristic adjustment circuit configured to unbalance the distortion component output from the first combiner; and a second combiner configured to combine the distortion component unbalanced by the frequency characteristic adjustment circuit with the fourth route signal.

### TECHNICAL FIELD

The present invention relates to a distortion compensation device applied to an amplification apparatus for satellite communication, an amplification apparatus for mobile communication, an amplification apparatus for terrestrial microwave communication, and the like and configured to suppress an intermodulation distortion.

### BACKGROUND ART

The highly-efficient amplification operation for reducing the consumed power and the low distortion operation for ensuring the communication quality are expected for an amplification apparatus configured to amplify an input signal formed of high-frequency signals having a plurality of frequencies. However, general amplification apparatuses have such a contradictory relationship that the efficiency is high at an operating point close to the saturated output power whereas a distortion characteristic deteriorates due to the non-linear operation. Thus, in order to achieve both the highly-efficient amplification operation and the low distortion operation, a distortion compensation device is used to improve a distortion.

Leakage of unnecessary power into an adjacent channel caused by an intermodulation distortion is well known as a problem caused by a distortion. In addition to this problem, there is a problem such as small signal suppression caused by non-linearity of an amplitude of a carrier wave of a high-frequency signal generated by an amplifier, because a high-power TV wave that is a video material to be relayed and a small-signal OW (Order Wire) wave that is a voice communication line between a relay vehicle and a studio of a TV station are amplified in common in a satellite communication application such as SNG (Satellite News Gathering) (refer to PTL 1).

A pre-distortion-type device including a diode is disclosed as a distortion compensation device configured to improve non-linearity of an amplitude and a phase of a carrier wave of a high-frequency signal and thereby improve an intermodulation distortion (refer to PTL 2).

An intermodulation distortion generated in an amplifier including a semiconductor amplification element may in some cases exhibit an unbalanced phenomenon in which the respective distortion components are different in frequency amplitude and phase. As a distortion compensation device taking this imbalance of the intermodulation distortion into consideration, there is disclosed a distortion compensation device configured to distribute an input signal into two routes, unbalance a level of a distortion component of the one route signal for each frequency by a frequency adjustment circuit, and then combine the one route signal with the other route signal (refer to PTL 3).

### CITATION LIST

### Patent Literature

PTL 1: Japanese Patent No. 5571047

PTL 2: Japanese Patent Laying-Open No. 2012-244545

PTL 3: Japanese Patent Laying-Open No. 2008-113077

### SUMMARY OF INVENTION

### Technical Problem

Although the configuration in PTL 2 can improve the non-linearity of the amplitude and the phase of the carrier wave of the high-frequency signal and thereby improve the intermodulation distortion, the configuration in PTL 2 has a problem of being unable to improve the imbalance of the intermodulation distortion. Although the configuration in PTL 3 can improve the imbalance of the intermodulation distortion, the configuration in PTL 3 has a problem of being unable to improve the non-linearity of the amplitude and the phase of the carrier wave of the high-frequency signal.

The present invention has been made to solve the above-described problems, and an object of the present invention is to obtain a distortion compensation device configured to compensate for non-linearity of an amplitude and a phase of a carrier wave of a high-frequency signal generated by a device to be compensated, such as an amplifier, and an imbalance of an intermodulation distortion.

### Solution to Problem

A distortion compensation device according to the present invention includes: a first distributor configured to distribute an input signal formed of signals having a plurality of frequencies into a first route signal and a second route signal, and output the first route signal and the second route signal; a distortion generation circuit configured to generate a distortion component in the input first route signal, and output the first route signal including the distortion component; a second distributor configured to receive the first route signal including the distortion component, distribute the first route signal including the distortion component into a third route signal and a fourth route signal, and output the third route signal and the fourth route signal; a first combiner configured to receive the second route signal and the third route signal, and extract and output the distortion component included in the third route signal; a frequency characteristic adjustment circuit configured to adjust an amplitude and a phase of the distortion component output from the first combiner for each frequency, thereby unbalancing the amplitude and the phase of the distortion component for each frequency; and a second combiner configured to combine the distortion component unbalanced by the frequency characteristic adjustment circuit with the fourth route signal, and output a combined signal. The distortion generation circuit has such non-linear characteristics that input/output characteristics thereof are opposite to those of a device to be compensated.

### Advantageous Effects of Invention

According to the present invention, there is obtained a distortion compensation device capable of compensating for non-linearity of an amplitude and a phase of a carrier wave of a high-frequency signal generated by a device to be compensated, and an imbalance of an intermodulation distortion.

### BRIEF DESCRIPTION OF DRAWINGS

FIG. 1 is a block diagram showing a configuration of an amplification apparatus according to a first embodiment of the present invention.

FIG. 2 is a block diagram showing a configuration of a distortion compensation device according to the first embodiment of the present invention.

FIG. 3 is a characteristic diagram of an amplifier according to the first embodiment of the present invention.

FIG. 4 is a characteristic diagram of an output signal of the amplification apparatus according to the first embodiment of the present invention.

FIG. 5 is a characteristic diagram of an input signal.

FIG. 6 is a characteristic diagram of the signal at a point A.

FIG. 7 is a characteristic diagram of the signal at a point B.

FIG. 8 is a characteristic diagram of the signal at a point C.

FIG. 9 is a characteristic diagram of the signal at a point D.

FIG. 10 is a characteristic diagram of the signal at a point E.

FIG. 11 is a characteristic diagram of the signal at a point F.

FIG. 12 is a block diagram of a distortion compensation device according to a second embodiment.

FIG. 13 is a characteristic diagram of a distortion generation circuit of the distortion compensation device according to the second embodiment.

FIG. 14 is a block diagram of a distortion compensation device according to a third embodiment.

FIG. 15 is a block diagram of a distortion compensation device according to a fourth embodiment.

FIG. 16 is a block diagram of a distortion compensation device according to a fifth embodiment.

### DESCRIPTION OF EMBODIMENTS

### First Embodiment

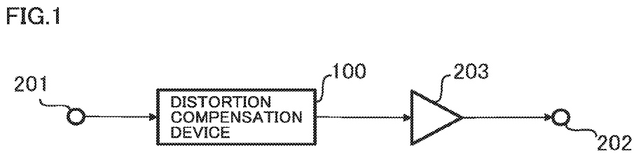

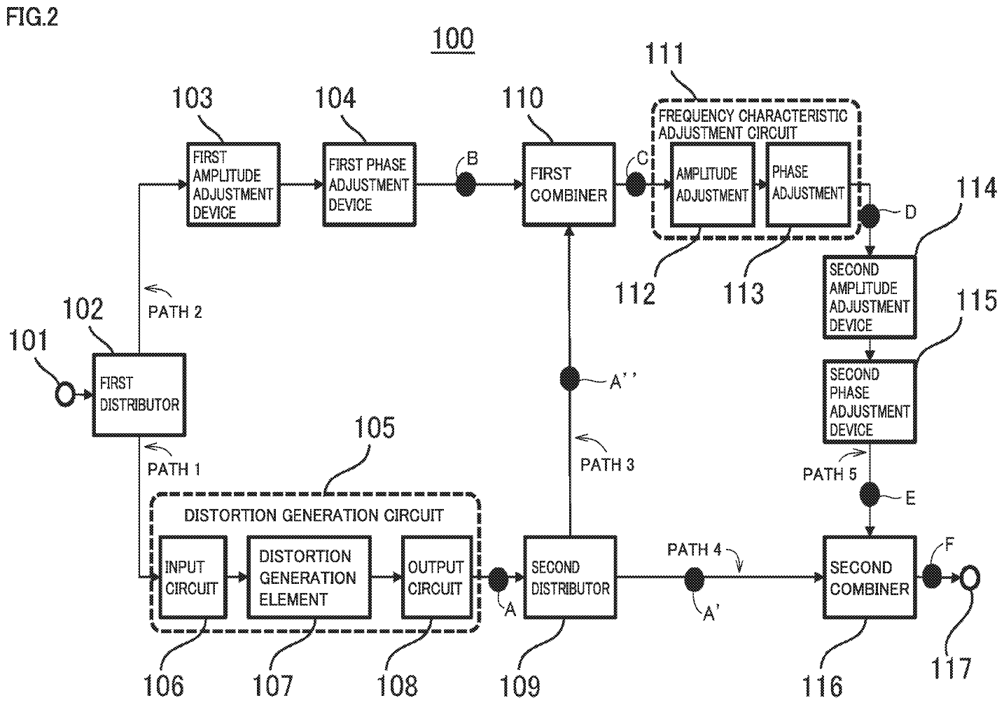

A first embodiment of the present invention will be described. FIG. 1 is a block diagram showing a configuration of an amplification apparatus according to the first embodiment of the present invention. FIG. 2 is a block diagram showing a configuration of a distortion compensation device 100 according to the first embodiment of the present invention.

In FIG. 1, the amplification apparatus includes an amplifier 203 that is a device to be compensated, and distortion compensation device 100 on the input side of amplifier 203. The amplification apparatus amplifies a high-frequency signal input into an input terminal 201 and formed of high-frequency signals having a plurality of different frequencies. The high-frequency signals having a plurality of different frequencies herein mean that the frequencies of carrier waves of the high-frequency signals are different.

Distortion compensation device 100 will be described with reference to FIG. 2. In FIG. 2, a first distributor 102 distributes the high-frequency signal input from an input terminal 101 connected to input terminal 201 in FIG. 1 into two route signals, i.e., a first route signal and a second route signal, and outputs the first route signal and the second route signal. The high-frequency signal input from the input terminal is a high-frequency signal formed of high-frequency signals having a plurality of different frequencies within a frequency band passing through distortion compensation device 100.

The first route signal is input into a distortion generation circuit 105, where a prescribed distortion component is generated and the first route signal including the prescribed distortion component is output. Distortion generation circuit 105 is formed by an input circuit 106, a distortion generation element 107 and an output circuit 108.

With respect to the first route signal input from first distributor 102, input circuit 106 adjusts input matching into distortion generation element 107, and outputs the first route signal to distortion generation element 107.

Distortion generation element 107 provides non-linear characteristics to a change in amplitude (gain) and phase of the first route signal input from input circuit 106 with respect to input power, and generates an intermodulation distortion (hereinafter denoted as “distortion component”). Then, distortion generation element 107 outputs the first route signal having the non-linear characteristics and including the distortion component to output circuit 108.

Output circuit 108 adjusts output matching from distortion generation element 107, and outputs the first route signal input from distortion generation element 107 and having the non-linear characteristics and including the distortion component to a second distributor 109.

Second distributor 109 distributes the first route signal, which has the non-linear characteristics and includes the distortion component, input from output circuit 108 into two route signals, i.e., a third route signal and a fourth route signal, and outputs the third route signal and the fourth route signal. Second distributor 109 outputs one signal (third route signal), of the distributed two route signals having the non-linear characteristics and including the distortion component, to a first combiner 110, and outputs the other signal (fourth route signal) to a second combiner.

The second route signal is input to a first amplitude adjustment device 103. First amplitude adjustment device 103 is formed by, for example, a variable attenuator or a variable gain amplifier, and adjusts an amplitude component of the second route signal input from first distributor 102. Then, first amplitude adjustment device 103 outputs the second route signal including the adjusted amplitude component to a first phase adjustment device 104.

First phase adjustment device 104 is formed by, for example, a variable phase shifter, and adjusts a phase component of the second route signal input from first amplitude adjustment device 103. Then, first phase adjustment device 104 outputs the second route signal including the adjusted phase component to first combiner 110.

First amplitude adjustment device 103 and first phase adjustment device 104 are also collectively referred to as a first amplitude and phase adjustment portion.

First combiner 110 combines the second route signal input from first phase adjustment device 104 with the third route signal, which has the non-linear characteristics and includes the distortion component, input from second distributor 109, to thereby extract the distortion component. First combiner 110 outputs the extracted distortion component to a frequency characteristic adjustment circuit 111 as a fifth route signal.

Frequency characteristic adjustment circuit 111 adjusts an amount of change in amplitude and an amount of change in phase due to the frequency characteristic, thereby unbalancing a level, for each frequency, of the distortion component input from first combiner 110 as the fifth route signal, in order to suppress a distortion component having an unbalanced level for each frequency and generated during amplification by amplifier 203. For example, frequency characteristic adjustment circuit 111 has one or both of a function portion 112 configured to adjust an inclination of the frequency characteristic of the amplitude like a frequency equalizer, and a function portion 113 configured to adjust an inclination of the frequency characteristic of the phase using a delay line. Frequency characteristic adjustment circuit 111 adjusts the amplitude and the phase of the distortion component extracted by first combiner 110 for each frequency and adjusts the frequency characteristic of the distortion component, thereby unbalancing an upper-side frequency band and a lower-side frequency band of the distortion component. Then, frequency characteristic adjustment circuit 111 outputs the distortion component to a second amplitude adjustment device 114 as the fifth route signal.

Second amplitude adjustment device 114 is formed by, for example, a variable attenuator or a variable gain amplifier, and adjusts the amplitude component of the distortion component of the fifth route signal input from frequency characteristic adjustment circuit 111, and the distortion component has the unbalanced upper-side and lower-side frequency bands. Then, first amplitude adjustment device 103 outputs, to a second phase adjustment device 115, the fifth route signal that is the distortion component including the adjusted amplitude component and having the unbalanced upper-side and lower-side frequency bands.

Second phase adjustment device 115 is formed by, for example, a variable phase shifter, and adjusts the phase component of the distortion component of the fifth route signal input from second amplitude adjustment device 114, and the distortion component has the unbalanced upper-side and lower-side frequency bands. Then, second phase adjustment device 115 outputs, to a second combiner 116, the fifth route signal that is the distortion component including the adjusted phase component and having the unbalanced upper-side and lower-side frequency bands.

Second combiner 116 combines the fourth route signal, which has the non-linear characteristics and includes the distortion component, input from second distributor 109 with the distortion component, which has the unbalanced upper-side and lower-side frequency bands, of the fifth route signal input from second phase adjustment device 115, to thereby obtain a combined signal. Then, second combiner 116 outputs the combined signal to an output terminal 117.

As an output signal, output terminal 117 outputs, to amplifier 203 in FIG. 1, the combined signal input from second combiner 116, and the combined signal includes the distortion component having the non-linear characteristics and the unbalanced upper-side and lower-side frequency bands.

A path (route) extending from an output end of first distributor 102 to an input end of second distributor 109 is referred to as a path 1 (route 1) and the input end is referred to as a point A. A path (route) extending from the output end of first distributor 102 through the first amplitude adjustment device and first phase adjustment device 104 to an input end of first combiner 110 is referred to as a path 2 (route 2) and the input end is referred to as a point B. A path (route) extending from an output end of second distributor 109 to the input end of first combiner 110 is referred to as a path 3 (route 3) and the input end is referred to as a point A″. A path (route) extending from the output end of second distributor 109 to an input end of second combiner 116 is referred to as a path 4 (route 4) and the input end is referred to as a point A′. A path (route) extending from first combiner 110 through frequency characteristic adjustment circuit 111, the second amplitude adjustment circuit and the second phase adjustment circuit to the input end of second combiner 116 is referred to as a path 5 (route 5), an output end of first combiner 110 is referred to as a point C, an output end of the frequency characteristic adjustment circuit is referred to as a point D, and the input end of the second combiner is referred to as a point E. Finally, an output end of the second combiner is referred to as a point F.

Next, a distortion compensation method in distortion compensation device 100 will be described with reference to FIG. 2.

When the input signal is input from input terminal 101, first distributor 102 of distortion compensation device 100 distributes the input signal into the two route signals (the first route signal and the second route signal). The input signal includes high-frequency signals having a plurality of frequencies.

Next, input circuit 106 adjusts input matching into distortion generation element 107, and distortion generation element 107 generates the non-linear characteristics and the distortion component in the input first route signal. Then, output circuit 108 adjusts output matching from distortion generation element 107. When distortion generation element 107 is formed by, for example, a diode, it is desirable that the non-linearity generated at this time should be optimized to counteract the non-linearity generated in amplifier 203, by using a bias current of the diode and impedance adjustment in input circuit 106 and output circuit 108 before and after distortion generation element 107.

Next, second distributor 109 distributes the first route signal having the non-linear characteristics and including the distortion component into the two route signals (the third route signal and the fourth route signal).

Next, first amplitude adjustment device 103 adjusts the amplitude component of the second route signal, and first phase adjustment device 104 adjusts the phase component of the second route signal.

Next, first combiner 110 combines the third route signal, which has the non-linear characteristics and includes the distortion component, input from second distributor 109 with the second route signal input from first phase adjustment device 104, extracts only the distortion component, and outputs the fifth route signal.

Next, frequency characteristic adjustment circuit 111 adjusts an amount of change in amplitude and an amount of change in phase of the input fifth route signal due to the frequency characteristic, thereby generating the distortion component having the unbalanced level for each frequency.

Next, second amplitude adjustment device 114 and second phase adjustment device 115 optionally adjust the amplitude and the phase of the distortion component, which has the unbalanced upper-side and lower-side frequency bands, of the fifth route signal input from frequency characteristic adjustment circuit 111. Thus, second amplitude adjustment device 114 and second phase adjustment device 115 adjust the amplitude and the phase to counteract the distortion component generated in amplifier 203, when second combiner 116 combines this signal with the fourth route signal input from second distributor 109.

The operation in each component in the first embodiment has been described above. Next, a mechanism for simultaneously compensating for the non-linearity of the amplitude and the phase of the distortion generated in the amplifier and the imbalance of the intermodulation distortion will be described with reference to FIGS. 2 to 11. The present embodiment will be described in connection with the case of two signals (f1 and f2) having different frequencies. f1 and f2 also represent frequencies of carrier waves of the respective signals (high-frequency signals).

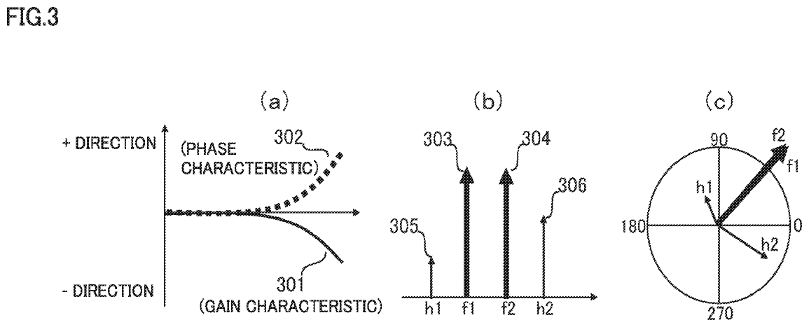

The case in which amplifier 203 has the gain characteristic and the phase characteristic having non-linear characteristics like a gain characteristic 301 indicated by a solid line and a phase characteristic 302 indicated by a dotted line, respectively, as shown in FIG. 3(a), and an intermodulation distortion h1 (305) in the lower-side frequency band and an intermodulation distortion h2 (306) in the upper-side frequency band have an amplitude imbalance shown in FIG. 3(b) and a phase imbalance shown in FIG. 3(c), respectively, will be discussed. In this case, in order that an amplification apparatus as a whole may compensate for the above-described non-linear characteristics and the above-described amplitude and phase imbalances and output distortion-free or small-distortion characteristics from output terminal 202 as shown in

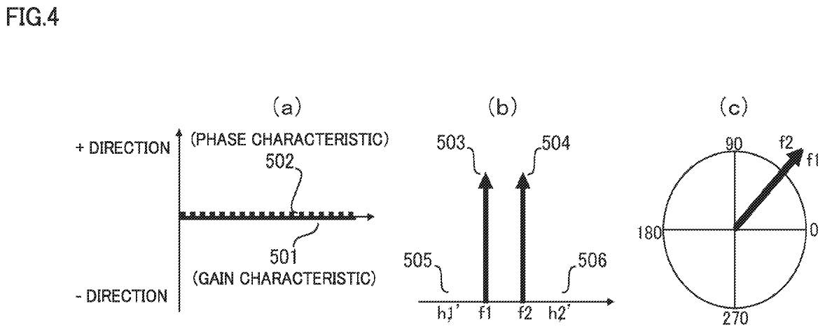

FIG. 4, it is necessary to output an intermodulation distortion h1′f (665) in the lower-side frequency band and an intermodulation distortion h2′f2 (666) in the upper-side frequency band from output terminal 117 in FIG. 2 to point F in FIG. 2 (output of second combiner 116 in FIG. 1). Intermodulation distortion h1′f (665) in the lower-side frequency band and intermodulation distortion h2′f2 (666) in the upper-side frequency band are such that, as shown in FIG. 11, the gain characteristic and the phase characteristic of signals f1 and f2 have non-linear characteristics like a gain characteristic 662 indicated by a solid line and a phase characteristic 661 indicated by a dotted line, respectively, which are opposite to gain characteristic 301 and phase characteristic 302 of amplifier 203, and intermodulation distortion h1′f (665) in the lower-side frequency band and intermodulation distortion h2′f2 (666) in the upper-side frequency band are identical in amplitude to and different in phase by 180° from intermodulation distortion h1 (305) in the lower-side frequency band and intermodulation distortion h2 (306) in the upper-side frequency band of amplifier 203. In FIG. 4(a), a gain characteristic 501 indicated by a solid line and a phase characteristic 502 indicated by a dotted line have linear characteristics. In FIG. 4(b), a signal f1 (503) and a signal f2 (504) are output, and an intermodulation distortion h1′ (505) and an intermodulation distortion h2′ (506) are not output. In FIG. 4(c), signal f1 and signal f2 are identical in phase.

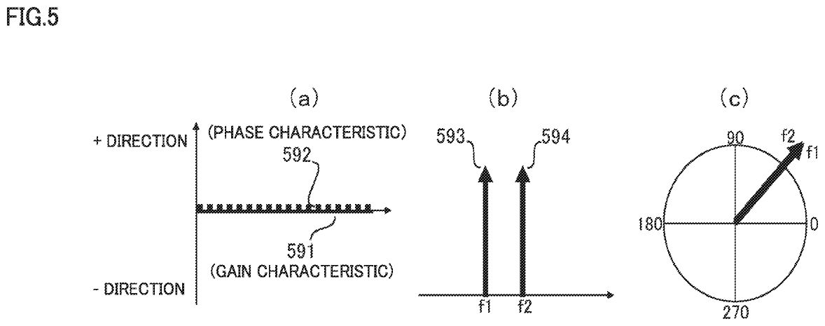

First, distortion-free signals f1 (593) and f2 (594) having a linear gain characteristic and a linear phase characteristic like a gain characteristic 591 indicated by a solid line and a phase characteristic 592 indicated by a dotted line, respectively, and not including an intermodulation distortion as shown in FIG. 5 are input into input terminal 101 in FIG. 2.

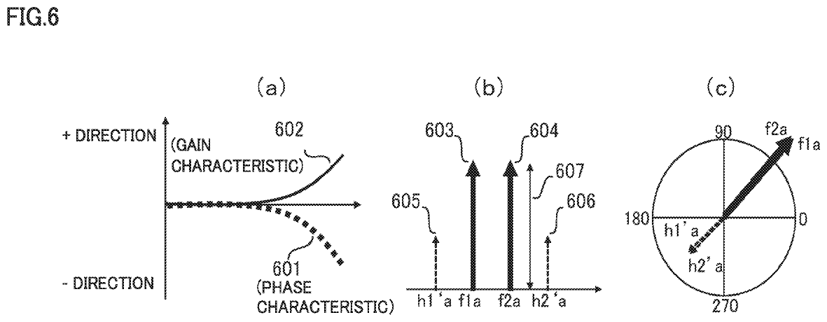

These signals f1 and f2 are distributed into path 1 on the distortion generation circuit 105 side and path 2 on the first amplitude adjustment device 103 side by first distributor 102. On path 1, by distortion generation circuit 105, at output point A of distortion generation circuit 105 in FIG. 2, a gain characteristic 602 indicated by a solid line and a phase characteristic 601 indicated by a dotted line have non-linear characteristics opposite to gain characteristic 301 and phase characteristic 302 of amplifier 203, while the amplitude and phase characteristics of an intermodulation distortion h1′a (605) in the lower-side frequency band and an intermodulation distortion h2′a (606) in the upper-side frequency band have an arbitrary size, as shown in FIG. 6. This signal is distributed into path 3 on the first combiner 110 side and path 4 on the second combiner 116 side by second distributor 109. Therefore, when the signal is equally distributed by the second distributor, the amplitude characteristic at point A′ or at point A″ is a half of the amplitude characteristic at point A. However, a distribution ratio is arbitrary.

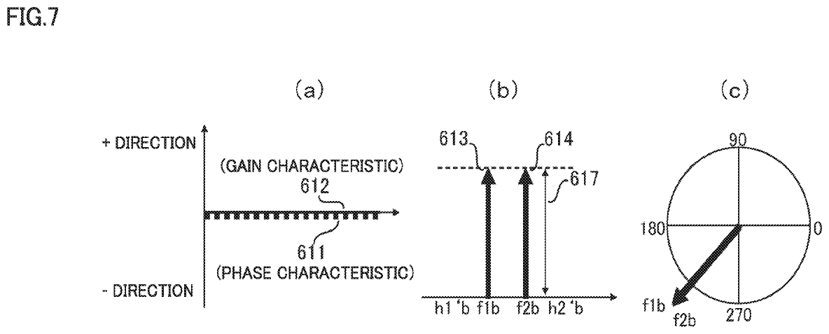

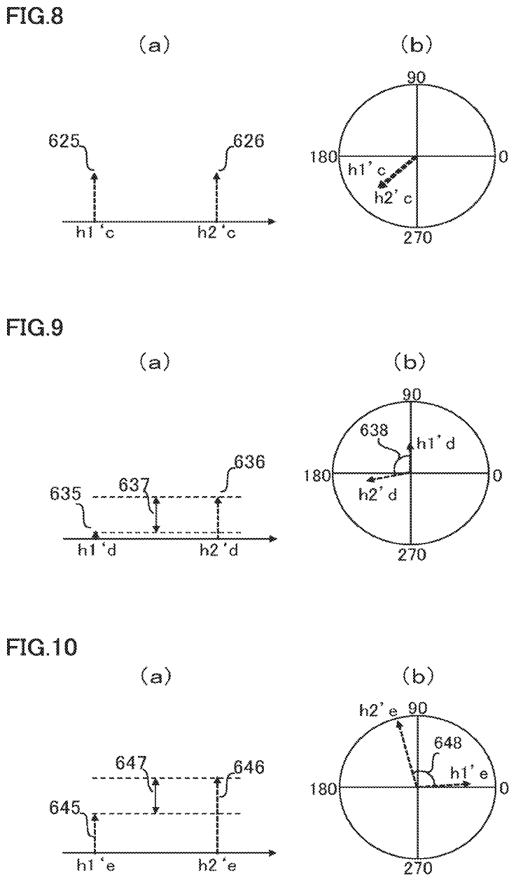

Next, on path 2 on the first amplitude adjustment device 103 side, by first amplitude adjustment device 103 and first phase adjustment device 104, distortion-free signals f1 (593) and f2 (594) distributed into path 2 by first distributor 102 are adjusted to be identical in amplitude to and opposite in phase to signals f1a (603) and f2a (604) at point A″ as shown in FIG. 7 at point B, and are output as signals f1b (613) and f2b (614). Therefore, at point C on path 5 that is the output side of first combiner 110, intermodulation distortion components h1′c (625) and h2′c (626) are extracted as shown in FIG. 8. That is, signals f1b (613) and f2b (614) are input into first combiner 110 in a state where an amplitude 607 of signals f1a (603) and f2a (604) is identical to an amplitude 617 of signals f1b (613) and f2b (614) and a phase of signals f1a (603) and f2a (604) is opposite to a phase of signals f1b (613) and f2b (614). Therefore, signals f1b and f2b are counteracted and intermodulation distortion components h1′c (625) and h2′c (626) are extracted and output.

Next, the frequency characteristics of extracted intermodulation distortion component h1′c (625) in the lower-side frequency band and intermodulation distortion component h2′c (626) in the upper-side frequency band are unbalanced by frequency characteristic adjustment circuit 111. As shown in FIG. 9, at output point D of the frequency characteristic adjustment circuit, an intermodulation distortion component h1′d (635) in the lower-side frequency band and an intermodulation distortion component h2′d (636) in the upper-side frequency band are adjusted to have an amplitude difference 637 and a phase difference 638.

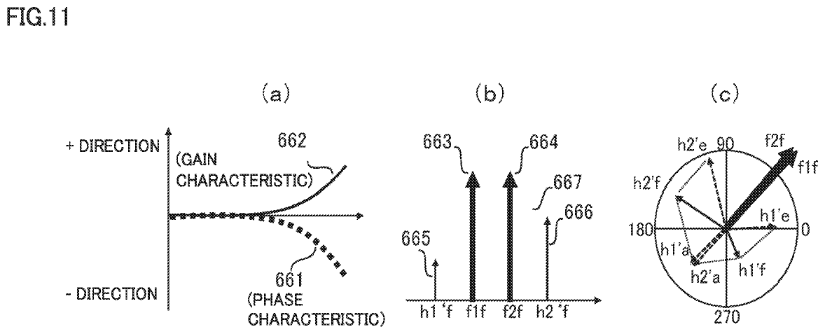

Next, by second amplitude adjustment device 114 and second phase adjustment device 115, the amplitude and phase characteristics of the intermodulation distortions are adjusted such that an intermodulation distortion h1′f (665) in the lower-side frequency band and an intermodulation distortion h2′f (666) in the upper-side frequency band are identical in amplitude to and opposite in phase to intermodulation distortion h1 (305) in the lower-side frequency band and intermodulation distortion h2 (306) in the upper-side frequency band of amplifier 203 at output point F of second combiner 116, after combination, by second combiner 116, with the signals output from second distributor 109 and having non-linear gain characteristic 601 and non-linear phase characteristic 602 opposite to gain characteristic 301 and phase characteristic 302 of the amplifier and including intermodulation distortion h1′a (605) in the lower-side frequency band and intermodulation distortion h2′a (606) in the upper-side frequency band. Then, as shown in FIG. 10, an intermodulation distortion h1′e (645) in the lower-side frequency band and an intermodulation distortion h2′e (646) in the upper-side frequency band are output at output point E of the second phase adjustment device. Amplitude difference 637 and phase difference 638 are basically maintained as an amplitude difference 647 and a phase difference 648.

Finally, by second combiner 116, the signals output from second distributor 109 are combined with intermodulation distortion h1′e (645) in the lower-side frequency band and intermodulation distortion h2′e (646) in the upper-side frequency band output from second phase adjustment device 115. The signals output from second distributor 109 are such that gain characteristic 602 indicated by the solid line and phase characteristic 601 indicated by the dotted line have non-linear characteristics opposite to gain characteristic 301 of amplifier 203 indicated by the solid line and phase characteristic 302 of amplifier 203 indicated by the dotted line, and the signals are intermodulation distortion h1′a (605) in the lower-side frequency band and intermodulation distortion h2′a (606) in the upper-side frequency band. Then, intermodulation distortion h1′f (665) in the lower-side frequency band and intermodulation distortion h2′f (666) in the upper-side frequency band are output from output terminal 117. Intermodulation distortion h1′f (665) in the lower-side frequency band and intermodulation distortion h2′f (666) in the upper-side frequency band are such that, as shown in FIG. 11, the gain characteristic and the phase characteristic of signals f1 and f2 have non-linear characteristics like gain characteristic 662 indicated by the solid line and phase characteristic 661 indicated by the dotted line, respectively, which are opposite to gain characteristic 301 of amplifier 203 indicated by the solid line and phase characteristic 302 of amplifier 203 indicated by the dotted line, and intermodulation distortion h1′f (665) in the lower-side frequency band and intermodulation distortion h2′f2 (666) in the upper-side frequency band are identical in amplitude to and different in phase by 180° from intermodulation distortion h1 (305) in the lower-side frequency band and intermodulation distortion h2 (306) in the upper-side frequency band.

As described above, according to the first embodiment, it is possible to simultaneously compensate for the non-linearity of the amplitude and the phase of the distortion generated in the amplifier and the imbalance of the intermodulation distortion. Therefore, the highly-efficient amplification operation and the low-distortion operation for ensuring the communication quality can be both achieved, and the cost of the apparatus and the consumed power during operation of a transmission apparatus can be reduced.

### Second Embodiment

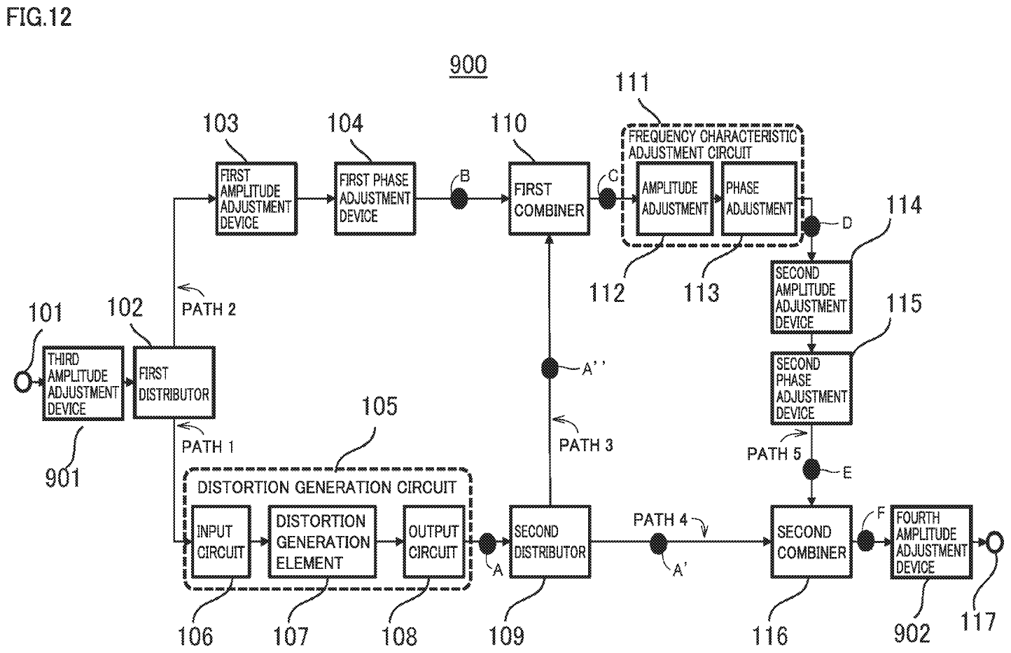

A second embodiment of the present invention will be described with reference to the figure. FIG. 12 is a block diagram of a distortion compensation device according to the second embodiment. As shown in FIG. 12, a distortion compensation device 900 according to the second embodiment is configured such that a third amplitude adjustment device 901 is arranged on the input side of first distributor 102 to control an amplitude of electric power input into distortion generation circuit 105 in distortion compensation device 100 according to the first embodiment shown in FIG. 2. In addition, a fourth amplitude adjustment device 902 is arranged on the output side of second combiner 116 to control an amplitude of electric power output from output terminal 117. In FIG. 12, the components that are the same as or equivalent to those in FIG. 2 are denoted by the same reference characters, and description thereof will not be repeated.

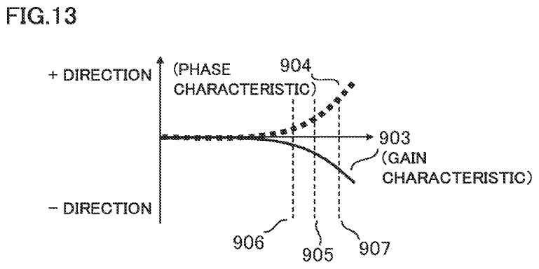

FIG. 13 shows non-linear characteristics of an amplitude and a phase of a signal generated in distortion generation circuit 105. Assuming that 905 represents a maximum value of the electric power input into distortion generation circuit 105 when third amplitude adjustment device 901 is not provided, the maximum value of the electric power input into distortion generation circuit 105 can be controlled by third amplitude adjustment device 901. That is, the operating point of distortion generation circuit 105 can be easily controlled. As a result, disturbance factors such as the electric power input into distortion compensation device 900, the temperature characteristic of the amplifier, and variations in the components, or amplifiers having different distortion characteristics can be dealt with in a flexible manner.

Similarly, the amplitude of the electric power output from output terminal 117 is controlled by fourth amplitude adjustment device 902, and thus, disturbance factors such as the temperature characteristic of the amplifier connected to distortion compensation device 900, and variations in the components, or amplifiers having different distortion characteristics and gains can be dealt with in a flexible manner.

### Third Embodiment

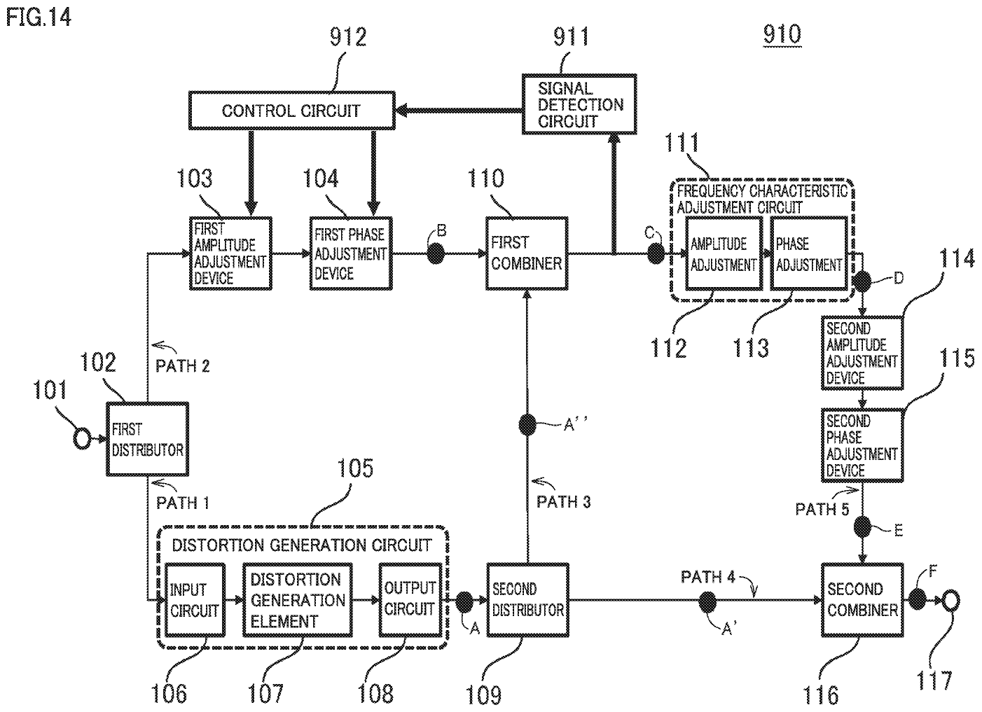

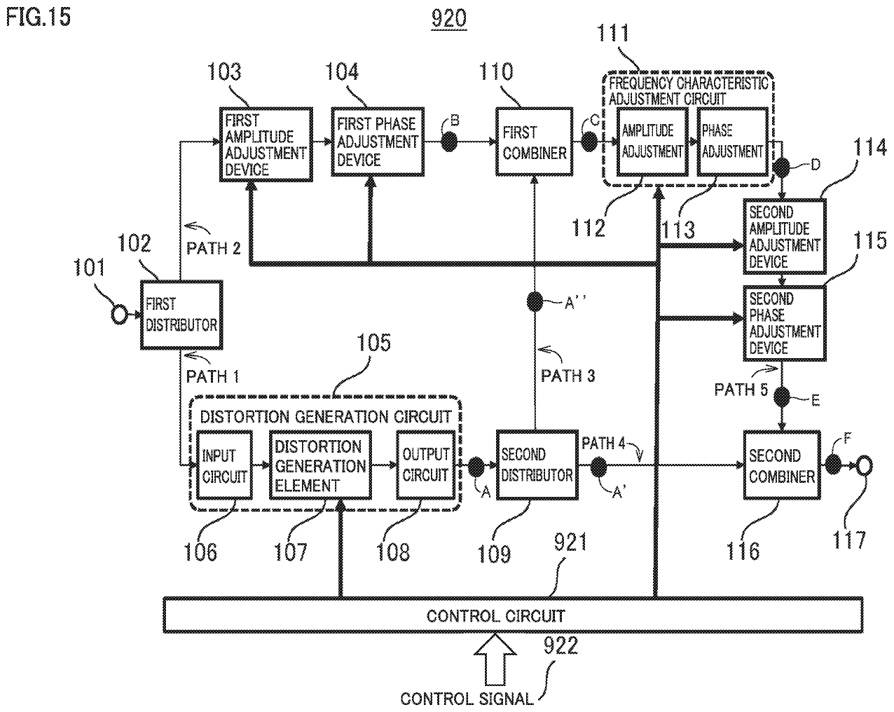

A third embodiment of the present invention will be described with reference to the figure. FIG. 14 is a block diagram of a distortion compensation device according to the third embodiment. As shown in FIG. 14, a distortion compensation device 910 according to the third embodiment is configured such that a signal detection circuit 911 detects electric power output from first combiner 110 and outputs a detection signal in distortion compensation device 100 according to the first embodiment shown in FIG. 2. A control circuit 912 is a device having the function of receiving the detection signal from signal detection circuit 911 and adjusting first amplitude adjustment device 103 and first phase adjustment device 104 such that an amount of electric power of the detection signal is minimized, i.e., signal f1 and signal f2 are completely counteracted at output point C of first combiner 110. In FIG. 14, the components that are the same as or equivalent to those in FIG. 2 are denoted by the same reference characters, and description thereof will not be repeated. Signal detection circuit 911 is also referred to as a monitor circuit, and the detection signal is also referred to as a monitor signal.

As a result, an influence of disturbance factors such as the electric power input into distortion compensation device 910, the temperature characteristic of the amplifier, and variations in the components on the compensation operation is minimized. In addition, extraction of a distorted wave in first combiner 110 becomes easy and accurate.

### Fourth Embodiment

A fourth embodiment of the present invention will be described with reference to the figure. FIG. 15 is a block diagram showing a configuration of a distortion compensation device 920 according to the fourth embodiment of the present invention. As shown in FIG. 15, distortion compensation device 920 according to the fourth embodiment is a distortion compensation device configured to control, in real time, distortion generation circuit 105, frequency characteristic adjustment circuit 111, first amplitude adjustment device 103, first phase adjustment device 104, second amplitude adjustment device 114, and second phase adjustment device 115 in distortion compensation device 100 according to the first embodiment shown in FIG. 1 through a control circuit 921 by using a control signal 922 provided from outside. In FIG. 15, the components that are the same as or equivalent to those in FIG. 2 are denoted by the same reference characters, and description thereof will not be repeated. Extraction of a distorted wave becomes easy and accurate.

Control signal 922 provided from outside is a signal preliminarily determined by, for example, monitoring a distortion input from table data corresponding to a change in temperature and a frequency or output from the amplifier, and calculating a value in real time such that the distortion is minimized. Accordingly, the performance of a communication apparatus as a whole, such as the temperature characteristic of the distortion, can be enhanced, and a reduction in distortion compensation function caused by a change over time can be prevented.

### Fifth Embodiment

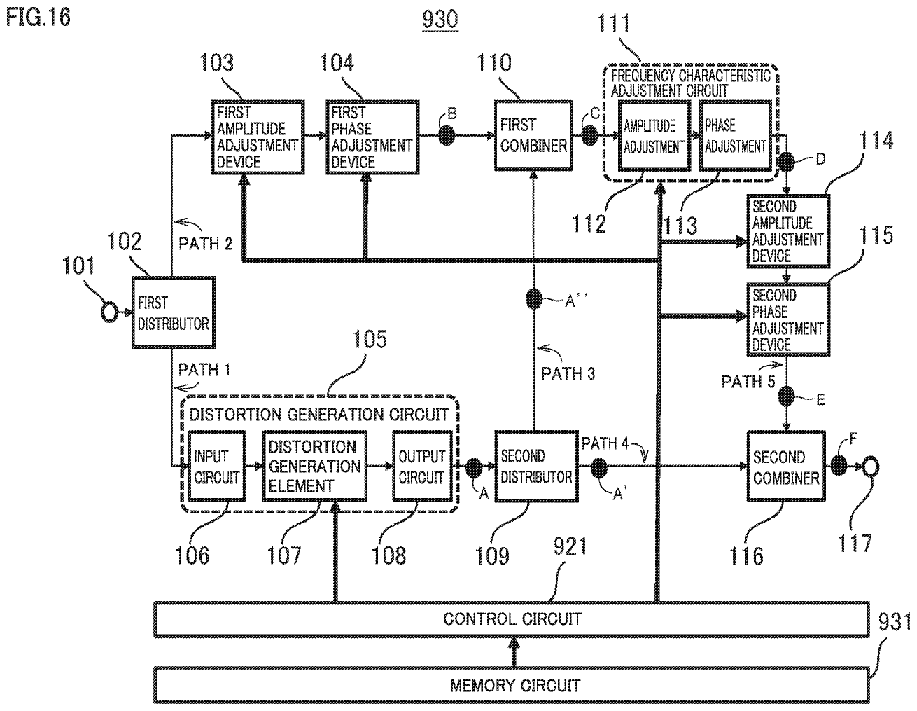

A fifth embodiment of the present invention will be described with reference to the figure. FIG. 16 is a block diagram showing a configuration of a distortion compensation device 930 according to the fifth embodiment of the present invention. As shown in FIG. 16, distortion compensation device 930 according to the fifth embodiment is a distortion compensation device configured to control, in real time, distortion generation circuit 105, frequency characteristic adjustment circuit 111, first amplitude adjustment device 103, first phase adjustment device 104, second amplitude adjustment device 114, and second phase adjustment device 115 in distortion compensation device 100 according to the first embodiment shown in FIG. 1 through control circuit 921 by using data stored in an internal memory circuit 931. In FIG. 16, the components that are the same as or equivalent to those in FIG. 2 are denoted by the same reference characters, and description thereof will not be repeated.

Distortion compensation table data corresponding to a change in temperature and a frequency is preliminarily written into internal memory circuit 931 and the data is used for control. Therefore, the number of components and the number of interfaces in a communication apparatus as a whole required for external control can be reduced, which contributes to a reduction in size and cost of the communication apparatus as a whole.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

100, 900, 910, 920, 930 distortion compensation device; 101, 201 input terminal; 102 first distributor; 103 first amplitude adjustment device; 104 first phase adjustment device; 105 distortion generation circuit; 106 input circuit; 107 distortion generation element; 108 output circuit; 109 second distributor; 110 first combiner; 111 frequency characteristic adjustment circuit; 112 amplitude adjustment portion; 113 phase adjustment portion; 114 second amplitude adjustment device; 115 second phase adjustment device; 116 second combiner; 117, 202 output terminal; 901 third amplitude adjustment device; 902 fourth amplitude adjustment device; 911 signal detection circuit (monitor circuit); 912, 921 control circuit; 922 control signal; 931 memory circuit.

1. A distortion compensation device connected to an input side of a device to be compensated, the distortion compensation device comprising:
a first distributor configured to distribute an input signal formed of signals having a plurality of frequencies into a first route signal and a second route signal, and output the first route signal and the second route signal;
a distortion generation circuit configured to generate a distortion component in the input first route signal, and output the first route signal including the distortion component;
a second distributor configured to receive the first route signal including the distortion component, distribute the first route signal including the distortion component into a third route signal and a fourth route signal, and output the third route signal and the fourth route signal;
a first combiner configured to receive the second route signal and the third route signal, and extract and output the distortion component included in the third route signal;
a frequency characteristic adjustment circuit configured to adjust an amplitude and a phase of the distortion component output from the first combiner for each frequency, thereby unbalancing the amplitude and the phase of the distortion component for each frequency; and
a second combiner configured to combine the distortion component unbalanced by the frequency characteristic adjustment circuit with the fourth route signal, and output a combined signal to the distortion compensation device,
the distortion generation circuit having such non-linear characteristics that input/output characteristics thereof are opposite to those of the device to be compensated.

2. The distortion compensation device according to claim 1, further comprising
an amplitude and phase adjustment circuit configured to adjust the second route signal to be identical in amplitude to and opposite in phase to the third route signal, and input the second route signal into the first combiner.

3. The distortion compensation device according to claim 2, further comprising:
a monitor circuit configured to monitor the distortion component output from the first combiner; and
a control circuit configured to control the amplitude and the phase in the amplitude and phase adjustment circuit based on a result of monitoring by the monitor circuit.

4. The distortion compensation device according to claim 2, further comprising
a control circuit configured to control the distortion generation circuit, the frequency characteristic adjustment circuit and the amplitude and phase adjustment circuit based on a control signal input from outside.

5. The distortion compensation device according to claim 2, further comprising
a control circuit configured to control the distortion generation circuit, the frequency characteristic adjustment circuit and the amplitude and phase adjustment circuit based on distortion compensation table data preliminarily stored in a memory circuit.

6. The distortion compensation device according to claim 1, further comprising:
an input-side amplitude adjustment device configured to adjust an amplitude of the input signal and output the input signal to the first distributor; and
an output-side amplitude adjustment device configured to adjust an amplitude of an output signal from the second combiner and output the output signal.

7. The distortion compensation device according to claim 2, further comprising:
an input-side amplitude adjustment device configured to adjust an amplitude of the input signal and output the input signal to the first distributor; and
an output-side amplitude adjustment device configured to adjust an amplitude of an output signal from the second combiner and output the output signal.

8. The distortion compensation device according to claim 3, further comprising:
an input-side amplitude adjustment device configured to adjust an amplitude of the input signal and output the input signal to the first distributor; and
an output-side amplitude adjustment device configured to adjust an amplitude of an output signal from the second combiner and output the output signal.

9. The distortion compensation device according to claim 4, further comprising:
an input-side amplitude adjustment device configured to adjust an amplitude of the input signal and output the input signal to the first distributor; and
an output-side amplitude adjustment device configured to adjust an amplitude of an output signal from the second combiner and output the output signal.

10. The distortion compensation device according to claim 5, further comprising:
an input-side amplitude adjustment device configured to adjust an amplitude of the input signal and output the input signal to the first distributor; and
an output-side amplitude adjustment device configured to adjust an amplitude of an output signal from the second combiner and output the output signal.
